(19) United States
(12) Patent Application Publication
(10) Pub. No.: US 2021/0158631 A1
(43) Pub. Date: May 27, 2021

(54) Vehicle, Control Method Thereof and Vehicle Trouble Diagnosis System.

(71) Applicants: Hyundai Motor Company, Seoul (KR); KIA Motors Corporation, Seoul (KR)

(72) Inventor: Jae Min Kwon, Incheon (KR)

(21) Appl. No.: 16/869,786

(22) Filed: May 8, 2020

(30) Foreign Application Priority Data
Nov. 25, 2019 (KR) 10-2019-0152692

(51) Int. Cl. G07C 5/00; G07C 5/08

(52) U.S. Cl. CPC G07C 5/006; G07C 5/008; G07C 5/0816; G07C 5/0808

(57) ABSTRACT

In accordance with one aspect of the disclosure, a vehicle capable of automatically diagnosing an electronic device of a vehicle and informing a manager of an electronic device trouble, includes: a plurality of controllers provided in the vehicle and configured to generate trouble code information; a plurality of electronic devices provided in the vehicle; a power controller configured to control the plurality of electronic devices; and a transceiver configured to transmit a trouble code information received from the plurality of controllers to a car sharing server when receiving a return signal of the vehicle from the car sharing server and transmit a trouble state information of the plurality of electronic devices received from the power controller to the car sharing server when receiving a diagnosis request signal of the vehicle from the car sharing server.

### CROSS-REFERENCE TO RELATED APPLICATION

This application is based on and claims priority under 35 U.S.C. § 119 to Korean Patent Application No. 10-2019-0152692, filed on Nov. 25, 2019 in the Korean Intellectual Property Office, the disclosure of which is incorporated herein by reference.

### BACKGROUND

### 1. Field

The disclosure relates to a vehicle, a control method thereof, and a vehicle trouble diagnosis system, and more particularly, to a vehicle capable of automatically diagnosing a trouble of an electronic device in a vehicle and informing an administrator, a control method thereof, and a vehicle trouble diagnosis system.

### 2. Description of the Related Art

In general, a vehicle means a vehicle that drives a road or a track using fossil fuel, electricity, and the like as a power source.

The vehicle includes a starting motor for starting the vehicle, and various electronic devices are provided to protect the driver and provide the driver with convenience and fun. In addition, the vehicle may include a generator for producing power supplied to the starting motor and the electronic devices, and a battery for storing the power produced by the generator.

In order to secure stability and convenience of vehicle operation, it is very important to periodically diagnose trouble of various parts and electronic devices provided in the vehicle.

In particular, the manager of a car sharing company must go directly to the shared vehicle and check whether the electronics of the shared vehicle are operating normally.

As a result, car-sharing companies are spending large amounts of money on labor costs.

### SUMMARY

Therefore, it is an aspect of the disclosure to provide a vehicle capable of automatically diagnosing an electronic device of a vehicle and informing a manager of an electronic device trouble, and a control method thereof and a vehicle trouble diagnosis system.

In particular, the manager of a car sharing company must go directly to the shared vehicle and check whether the electronics of the shared vehicle are operating normally.

In accordance with one aspect of the disclosure, a vehicle includes: a plurality of controllers provided in the vehicle and configured to generate trouble code information; a plurality of electronic devices provided in the vehicle; a power controller configured to control the plurality of electronic devices; and a transceiver configured to transmit a trouble code information received from the plurality of controllers to a car sharing server when receiving a return signal of the vehicle from the car sharing server and transmit a trouble state information of the plurality of electronic devices received from the power controller to the car sharing server when receiving a diagnosis request signal of the vehicle from the car sharing server.

The vehicle may further include: a current sensor configured to measure a current value flowing through the plurality of electronic devices, wherein the power controller is configured to transmit a control signal for operating the plurality of electronic devices when receiving the diagnosis request signal from the car sharing server and determine a trouble state of the plurality of electronic devices based on a difference between a maximum value and a minimum value of the current value measured by the current sensor.

The power controller may be configured to determine that at least one of the plurality of electronic devices is in a trouble when a difference between the maximum value and the minimum value of the current value measured by the current sensor is less than or equal to a predetermined value after transmitting the control signal.

The power controller may be configured to sequentially transmit control signals for operating each of the plurality of electronic devices, and transmit a trouble state of the electronic device determined to be in a trouble among the plurality of electronic devices to the transceiver.

The transceiver may be configured to request the plurality of controllers for the trouble code information when receiving a return signal of the vehicle from the car sharing server.

The transceiver may be configured to request the power controller for trouble state information of the plurality of electronic devices when receiving a diagnosis request signal of the vehicle from the car sharing server.

The vehicle may further include: a Tire Pressure Monitoring System (TPMS) configured to measure a tire air pressure of the vehicle, and the transceiver may be configured to request the tire pressure information of the vehicle to the TPMS when receiving a diagnosis request signal of the vehicle from the car sharing server and transmit the tire air pressure information of the vehicle received from the TPMS to the car sharing server.

In accordance with another aspect of the disclosure, a control method of a vehicle, include: receiving at least one of a return signal of the vehicle or a diagnosis request signal of the vehicle from a car sharing server; when receiving the return signal of the vehicle from the car sharing server, transmitting trouble code information generated by a plurality of controllers provided in the vehicle to the car sharing server; when receiving the diagnosis request signal of the vehicle from the car sharing server, determining a trouble state of a plurality of electronic devices of the vehicle; and transmitting the trouble state information of the plurality of electronic devices to the car sharing server.

The determining the trouble state of the plurality of electronic devices may include: transmitting a control signal for operating the plurality of electronic devices; measuring a current value flowing through the plurality of electronic devices; and determining the trouble state of the plurality of electronic devices based on a difference between a maximum value and a minimum value of current value flowing through the plurality of electronic devices.

The determining the trouble state of the plurality of electronic devices may include: determining that at least one of the plurality of electronic devices is in a trouble when a difference between a minimum value and a maximum value of current value flowing through the plurality of electronic devices is equal to or less than a predetermined value after transmitting the control signal.

The determining the trouble state of the plurality of electronic devices and transmitting the trouble state information of the plurality of electronic devices to the car sharing server may include: sequentially transmitting control signals for operating each of the plurality of electronic devices; and transmitting the trouble state of the electronic device determined to be in a trouble among the plurality of electronic devices to the car sharing server.

The control method may further include: requesting the plurality of controllers for the trouble code information when receiving a return signal of the vehicle from the car sharing server.

The control method may further include: requesting the power controller for trouble state information of the plurality of electronic devices when receiving a diagnosis request signal of the vehicle from the car sharing server.

The control method may further include: when receiving a diagnosis request signal of the vehicle from the car sharing server, transmitting the tire air pressure information of the vehicle to the car sharing server.

In accordance with another aspect of the disclosure, a vehicle trouble diagnosis system, include: a car sharing server configured to receive a return signal of the vehicle or a diagnosis request signal of the vehicle from a user terminal and to transmit at least one of the return signal or the diagnosis request signal to the vehicle; and a vehicle configured to transmit a trouble code information of the vehicle to the car sharing server when receiving the return signal from the car sharing server and transmit a trouble state information of the plurality of electronic devices of the vehicle to the car sharing server when receiving the diagnosis request signal from the car sharing server.

The car sharing server may be configured to match at least one of the trouble code information received from the vehicle or the trouble state information of the plurality of electronic devices with a unique number of the vehicle and to store the same.

The car sharing server may be configured to determine whether to repair the vehicle based on at least one of the trouble code information received from the vehicle or the trouble state information of the plurality of electronic devices

The car sharing server may be configured to transmit a repair request signal to the vehicle when determining that the repair of the vehicle is necessary.

The vehicle may be configured to move to a predetermined place based on the autonomous driving system when receiving the repair request signal from the car sharing server.

The vehicle may be configured to transmit a control signal for operating the plurality of electronic devices when receiving a diagnosis request signal from the car sharing server and determine a trouble state of the plurality of electronic devices based on a difference between a maximum value and a minimum value of current values flowing through the plurality of electronic devices after transmitting the control signal.

### BRIEF DESCRIPTION OF THE DRAWINGS

These and/or other aspects of the disclosure will become apparent and more readily appreciated from the following description of the embodiments, taken in conjunction with the accompanying drawings of which:

FIG. 1 is a schematic diagram of a vehicle trouble diagnosis system according to an embodiment of the disclosure.

FIG. 2 is a block diagram illustrating a configuration of a vehicle according to an embodiment of the disclosure.

FIG. 3 is a flowchart illustrating a control method of a vehicle according to an embodiment of the disclosure.

FIG. 4 is a flowchart illustrating another control method of a vehicle according to an embodiment of the disclosure.

FIG. 5A is a graph illustrating a current value measured by a current sensor when the electronic device of the vehicle according to an embodiment of the disclosure does not operate.

FIG. 5B is a graph illustrating a current value measured by a current sensor when the electronic device of the vehicle according to an embodiment of the disclosure operates.

### DETAILED DESCRIPTION

Like numerals refer to like elements throughout the specification. Not all elements of embodiments of the disclosure will be described, and description of what are commonly known in the art or what overlap each other in the embodiments will be omitted. The terms as used throughout the specification, such as part“, module”, member“, block”, etc., may be implemented in software and/or hardware, and a plurality of parts“, modules”, members“, or blocks” may be implemented in a single element, or a single part“, module”, member“, or block” may include a plurality of elements.

It will be further understood that the term “connect” or its derivatives refer both to direct and indirect connection, and the indirect connection includes a connection over a wireless communication network.

It will be further understood that the terms “comprises” and/or “comprising,” when used in this specification, identify the presence of stated features, integers, steps, operations, elements, and/or components, but do not preclude the presence or addition of one or more other features, integers, steps, operations, elements, components, and/or groups thereof, unless the context clearly indicates otherwise.

In the specification, it will be understood that, when a member is referred to as being “on/under” another member, it can be directly on/under the other member, or one or more intervening members may also be present.

The terms including ordinal numbers like “first” and “second” may be used to explain various components, but the components are not limited by the terms. The terms are only for the purpose of distinguishing a component from another.

As used herein, the singular forms “a,” “an” and “the” are intended to include the plural forms as well, unless the context clearly indicates otherwise.

Reference numerals used for method steps are just used for convenience of explanation, but not to limit an order of the steps. Thus, unless the context clearly dictates otherwise, the written order may be practiced otherwise.

Hereinafter, the operating principles and embodiments of the disclosure will be described with reference to the accompanying drawings.

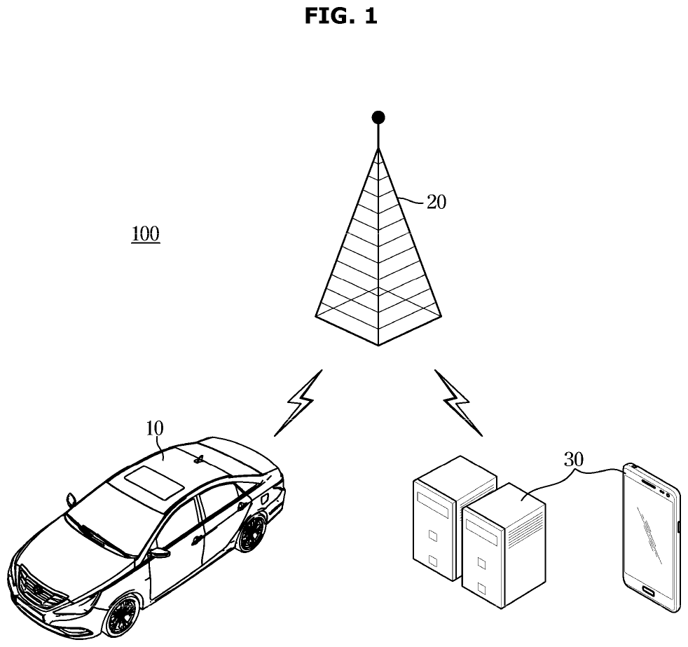

FIG. 1 is a schematic diagram of a vehicle trouble diagnosis system according to an embodiment of the disclosure.

Referring to FIG. 1, a vehicle trouble diagnosis system 100 according to an embodiment may include a user terminal 30 which receives a return command of the vehicle 10 from a user or a manager or receives a diagnostic request command, a car sharing server 20 which receives a return signal of the vehicle 10 from the user terminal 30 or receives a diagnosis request signal of the vehicle 10 and transmits a return signal and a diagnosis request signal to the vehicle 10 and the vehicle 10 which receives a return signal and a diagnosis request signal from the car sharing server 20.

According to an embodiment, the user terminal 30 may refer to all terminal devices that can communicate with a car sharing server 20 using a wireless communication network. For example, the user terminal 30 may include a smart phone, a laptop, a computer, and the like.

In addition, the user terminal 30 according to an embodiment may mean a terminal device of a consumer of a car sharing service that temporarily uses the shared vehicle 10 or a manager of a company providing a car sharing service.

The car sharing server 20 according to an embodiment may receive and store an information such as an information related to the reservation of the vehicle 10, an information related to the use of the vehicle 10, and an information related to the diagnosis of the vehicle 10 from the user terminal 30.

In addition, when the car sharing server 20 receives the reservation information from the user terminal 30, the car sharing server 20 may provide a control right of the vehicle 10 to the user of the user terminal 30 based on the reservation information. And when the car sharing server 20 receives the vehicle 10 return signal from the user terminal 30, the car sharing server 20 may recover the control right of the vehicle 10 from the user of the user terminal 30.

For example, when receiving information that a specific user has reserved the vehicle 10 from 2 pm to 4 pm, the car sharing server 20 may grant a control right to control the vehicle 10 to the user terminal 30 of a specific user at 2 pm. Further, when the vehicle 10 is in a predetermined position at 4 pm and receiving a vehicle 10 return signal from the user, the control right to control the vehicle 10 may be recovered from the user terminal 30 of the specific user.

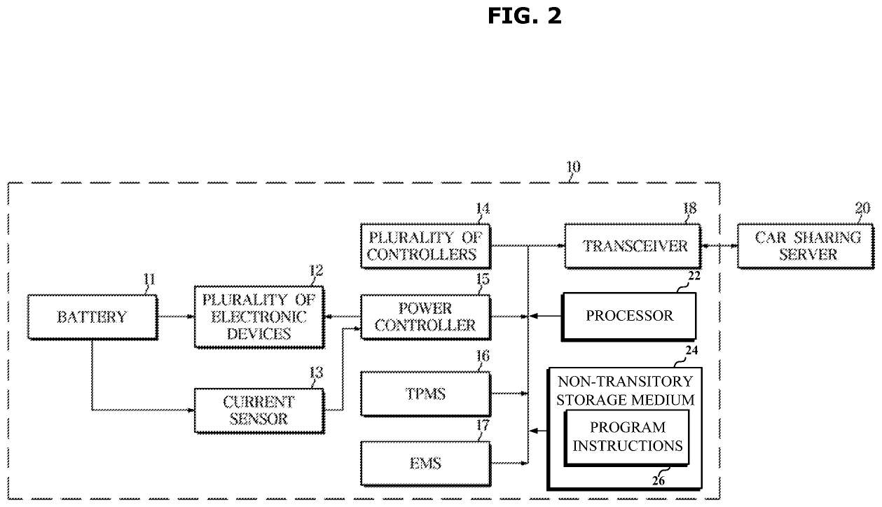

The vehicle 10 according to an embodiment may receive various information from the car sharing server 20 and transmit information related to the diagnosis of the vehicle 10 to the car sharing server 20. This will be described later in detail with reference to FIG. 2.

FIG. 2 is a block diagram illustrating a configuration of a vehicle according to an embodiment of the disclosure. Referring to FIG. 2, the vehicle 10 according to an embodiment may include a plurality of controllers 14 for generating trouble code information, a battery 11 for providing power, a plurality of electronic devices 12 using power stored in the battery 11 as a power source, a current sensor 13 measuring current flowing through the plurality of electronic devices 12, a power controller 15 for controlling a plurality of electronic devices 12, a tire pressure monitoring system 16 (TPMS) for measuring a tire air pressure of the vehicle (10), an engine management system 17 (EMS) for detecting an engine operating state of the vehicle 10 and a transceiver 18 capable of communicating with the car sharing server 20. The vehicle 10 may also include a processor 22, a non-transitory storage medium 24 containing program instructions 26 that, when executed by the processor 22, causes the transceiver 18 to perform operations discussed in detail below.

A plurality of controllers 14 according to an embodiment may mean each controller for operating each subsystem of the vehicle 10, and the each controller may generate trouble code information that can determine whether each subsystem is in trouble. For example, the plurality of controllers 14 may include a body control module (BCM), an engine control module (ECM), a transmission control module (TCM), a powertrain control module (PCM), a brake control module (EBCM), a sensor diagnostic module (SDM) and a power steering control module (PSCM) and the like. Of course, the plurality of controllers 14 may include any configuration that controls the operation of the vehicle 10.

In addition, the plurality of controllers 14 may be implemented as a memory for storing the data for the algorithm for controlling the operation of the vehicle 10 or the program for reproducing the algorithm and a processor for performing the above-described operations using the data stored in the memory.

The trouble code information generated by the plurality of controllers 14 may mean a code that may be formed of alphabets and numbers so as to identify which subsystem of the vehicle 10 has a problem, but is not limited thereto.

The plurality of controllers 14 may transmit trouble code information generated according to the request of the transceiver 18 to the transceiver 18.

The power controller 15 according to an embodiment may mean an indoor integrated power controller (ICU). The power controller 15 may control the plurality of electronic devices 12 using the power stored in the battery 11.

In this case, the plurality of electronic devices 12 may refer to electronic devices that use electricity stored in the battery 11 of the vehicle 10 as a power source. For example, the plurality of electronic devices 12 may include external lamp loads such as head lamps, stop lamps, and turn lamps, and may include motor loads such as a motor for wiper operation and a motor for door lock/unlock.

In addition, the power controller 15 may be implemented as a memory for storing the data for the algorithm for controlling the operation of the plurality of electronic devices 12 or the program for reproducing the algorithm and a processor for performing the above-described operations using the data stored in the memory.

The battery 11 according to an embodiment may store the power produced by the generator, and supply power to the plurality of electronic devices 12 included in the vehicle 10. For example, the generator may generate power from the rotation of the engine while the vehicle 10 is running, and the battery 11 may receive power from the generator and store power (electrical energy). In addition, the battery 11 may supply power for starting the starter motor to drive the vehicle 10 or may supply power to the plurality of electronic devices 12 of the vehicle 10.

According to an embodiment, the current sensor 13 may obtain state information related to the battery 11, and thus may measure current values flowing through the plurality of electronic devices 12. For example, the current sensor 13 may refer to a current sensor measuring the input/output current of the battery 11.

The current sensor 13 may transmit the current value measured through local interconnect network (LIN) communication to the power controller 15.

A tire pressure monitoring system (TPMS) 16 according to an embodiment may measure tire air pressure of the vehicle 10. Specifically, the TPMS 16 refers to a device in which a sensor mounted inside the tire senses the pressure of the tire, or pressure and temperature of the tire, and displays this information to the driver so that the driver can check the tire pressure state in real time.

Although the TPMS 16 and the plurality of controllers 14 are separately shown in FIG. 2, one configuration of the TPMS 16 may be included in the plurality of controllers 14 to generate a trouble diagnostic code.

An engine management system (EMS) 17 according to an embodiment may mean an electronic device for controlling an engine of the vehicle 10. Specifically, the EMS 17 may include various sensors for maximizing engine driving force acceleration, minimizing fuel consumption rate, minimizing engine noise, and the like.

Although the EMS 17 and the plurality of controllers 14 are separately shown in FIG. 2, one configuration of the EMS 17 may be included in the plurality of controllers 14 to generate a trouble diagnostic code.

The plurality of controllers 14, power controllers 15, TPMS 16, and EMS 17 described above may communicate with the transceiver 18 using an Ethernet, a media oriented systems transport (MOST), a Flex-ray, a controller area network (CAN), a local interconnect network (LIN) in the vehicle 10, or the like.

For example, the plurality of controllers 14 may transmit trouble code information to the transceiver 18, the power controller 15 may transmit trouble state information of the plurality of electronic devices 12 to the transceiver 18, the TPMS 16 may transmit tire air pressure information to transceiver 18, and the EMS 17 may transmit engine trouble information to transceiver 18.

The transceiver 18 according to an embodiment may include a connectivity control unit (CCU). The transceiver 18 may include a communication module capable of performing a vehicle 10 network communication such as controller area network (CAN) communication, local interconnect network (LIN) communication, Flex-Ray communication, Ethernet, a media oriented systems transport (MOST), etc., and a communication module capable of performing wireless Internet communication such as a wireless LAN (WLAN), a wireless broadband (Wibro), a Wi-Fi, a world interoperability for microwave access (WiMAX) and high speed downlink packet access (HSDPA).

As described above, the transceiver 18 may exchange data with the plurality of controllers 14, the power controller 15, the TPMS 16, and the EMS 17. For example, the transceiver 18 may transmit a signal for requesting trouble code information to the plurality of controllers 14 and receive trouble code information from the plurality of controllers 14, and may transmit a signal requesting the power controller 15 to trouble state information of the plurality of electronic devices 12, and receive the trouble state Information of the plurality of electronic devices 12 from the power controller 15.

In addition, the transceiver 18 may transmit and receive various data by performing wireless Internet communication with the car sharing server 20. For example, the transceiver 18 may receive the return signal of the vehicle 10 from the car sharing server 20 and transmit trouble code information received from the plurality of controllers 14 to the car sharing server 20. In addition, the transceiver 18 may receive the diagnosis request signal of the vehicle 10 from the car sharing server 20, and transmit the trouble state information of the plurality of electronic devices 12 to the car sharing server 20.

The transceiver 18 may be implemented as a memory for storing the data for the algorithm for communicating with the car sharing server 20 or various components inside the vehicle 10 or the program for reproducing the algorithm and a processor for performing the above-described operations using the data stored in the memory, and may include at least one transceiver for transmitting and receiving a variety of information.

Although not shown in the drawings, the vehicle 10 may have an autonomous driving system, and the autonomous driving system may move the vehicle 10 to a desired destination without the driver's intervention if only the purpose of the vehicle 10 is set

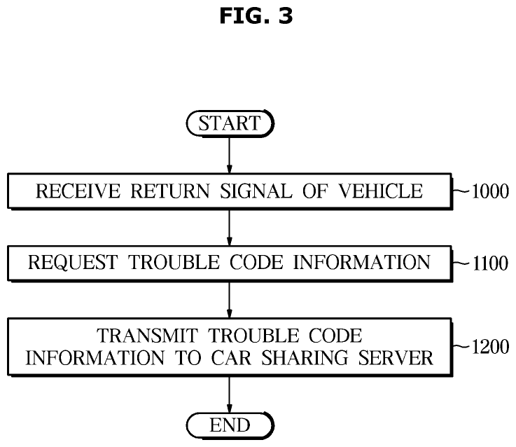

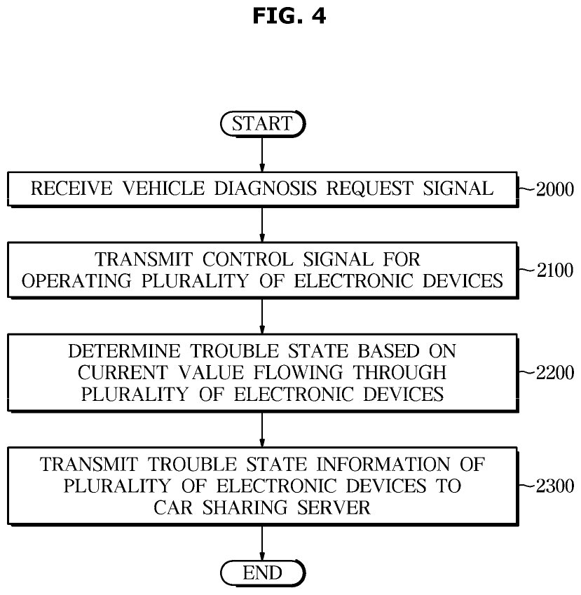

Hereinafter, a method of controlling the vehicle 10 using each configuration of the vehicle 10 described above will be described in detail with reference to FIGS. 3 to 4. FIGS. 3 to 4 are flowcharts illustrating a control method of a vehicle according to an embodiment of the disclosure.

Referring to FIG. 3, the car sharing server 20 according to an embodiment receives a return signal of the vehicle 10 from the user terminal 30, and when determining that the return of the vehicle 10 is completed, the car sharing server 20 may transmit the return signal of the vehicle 10 to the vehicle (10). The transceiver 18 of the vehicle 10 according to an embodiment may receive the return signal of the vehicle 10 from the car sharing server 20 (1000).

In this case, the return signal of the vehicle 10 refers to a signal transmitted by a user of the shared vehicle 10 to return the vehicle 10 after finishing using the shared vehicle 10.

When the transceiver 18 receives the return signal of the vehicle 10 from the car sharing server 20, the transceiver 18 may request trouble code information from the plurality of controllers 14 (1100).

When the plurality of controllers 14 receives the request for the trouble code information from the transceiver 18, the plurality of controllers 14 may transmit the trouble code information to the transceiver 18, and the transceiver 18 may receive the trouble code information from the plurality of controllers 14.

Thereafter, the transceiver 18 may transmit the trouble code information received from the plurality of controllers 14 to the car sharing server 20 (1200).

Although not shown in the drawing, the car sharing server 20 may match trouble code information received from the vehicle 10 with a unique number of the vehicle 10 and store the same. The unique number of the vehicle 10 may refer to a number for identifying the vehicle 10, such as a license plate number of the vehicle 10. The car sharing server 20 may determine the type of the vehicle 10 related to the unique number of the vehicle 10, match the trouble code information with the type of the vehicle 10, and store the same. The car sharing server 20 may easily manage the plurality of shared vehicles 10 by matching trouble code information received from the vehicle 10 with a unique number of the vehicle 10 and storing the same.

In addition, the car sharing server 20 determines whether to repair the vehicle 10 based on the trouble code information received from the vehicle 10, when determining that the vehicle 10 needs repair, the car sharing server 20 may transmit a repair request signal to the vehicle 10.

According to the control method of the vehicle 10 according to the above-described embodiment, when the user parks the vehicle 10 at a designated position, and transmits the return signal of the vehicle 10 to the car sharing server by using the user terminal 30, the car sharing server 20 can grasp the trouble code information of the vehicle 10. For this reason, the manager of the car sharing company does not need to go directly to the shared vehicle and check whether the plurality of controllers of the shared vehicle operate normally.

Although not shown in the drawing, when the transceiver 18 of the vehicle 10 receives a repair request signal from the car sharing server 20, the autonomous vehicle may move to a predetermined place based on the autonomous driving system.

In this case, the predetermined place may be determined as the vehicle 10 repair service center closest to the return place of the vehicle 10.

Referring to FIG. 4, the car sharing server 20 according to an embodiment may receive a vehicle (10) diagnosis request signal from the user terminal 30 and transmit the received vehicle (10) diagnosis request signal to the vehicle (10), and the transceiver 18 of the vehicle 10 may receive a vehicle 10 diagnosis request signal from the car sharing server 20 (2000).

At this time, the vehicle (10) diagnosis request signal may include a vehicle (10) return signal transmitted by a user of the shared vehicle (10) to return the vehicle (10) after the use of the shared vehicle (10), and may include a signal separately transmitted by a manager of the shared vehicle 10 to diagnose the electronic device 12 of the shared vehicle 10.

As will be described later, in order to determine trouble states of the plurality of electronic devices 12 of the vehicle 10, an operation of driving the plurality of electronic devices 12 is required. Therefore, there is a problem that the battery 11 of the vehicle 10 may be quickly consumed. That is, when the diagnosis request signal is the vehicle (10) return signal, since the trouble state of the plurality of electronic devices 12 is determined whenever the use of the vehicle 10 by the user of the shared vehicle 10 is terminated, the battery 11 of the vehicle 10 may be quickly exhausted.

However, in order to accurately determine the cause of trouble of the plurality of electronic devices 12, it may be preferable that the diagnosis request signal is the vehicle 10 return signal.

When the transceiver 18 receives the diagnosis request signal of the vehicle 10 from the car sharing server 20, the transceiver 18 may request trouble state information of the plurality of electronic devices 12 from the power controller 15.

When the power controller 15 receives a signal for requesting trouble state information from the transceiver 18, the power controller 15 may transmit a control signal for operating the plurality of electronic devices 12 (2100).

Thereafter, the power controller 15 may determine a trouble state of the plurality of electronic devices 12 based on the current value measured by the current sensor 13 (2200). That is, the trouble state of the plurality of electronic devices 12 may be determined based on the current values flowing through the plurality of electronic devices 12.

For example, when the difference between the maximum value and the minimum value of the current value measured by the current sensor 13 after transmitting the control signal is less than or equal to a predetermined value, the power controller 15 may determine that one of the plurality of electronic devices 12 is in a trouble.

Specifically, the power controller 15 may sequentially transmit control signals for operating each of the plurality of electronic devices 12, and determine a troubled electronic device among the plurality of electronic devices 12.

For example, assuming that the plurality of electronic devices 12 include a head lamp and a stop lamp, the power controller 15 may transmit a control signal for operating the head lamp to determine whether the head lamp is in a trouble, and sequentially transmit the control signal for operating the stop lamp to determine whether the stop lamp is in a trouble.

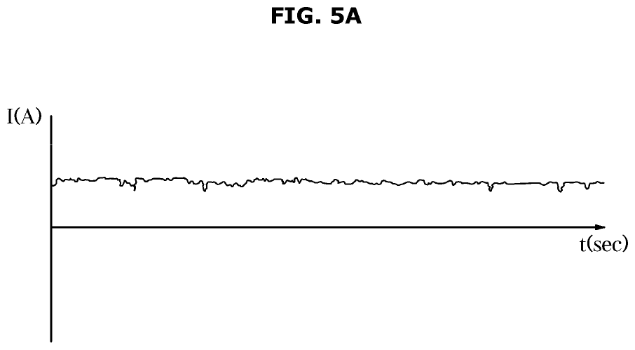

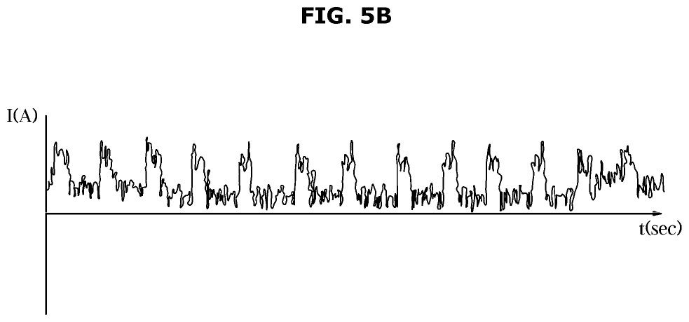

FIG. 5A is a graph illustrating a current value measured by a current sensor when the electronic device of the vehicle according to an embodiment of the disclosure does not operate. FIG. 5B is a graph illustrating a current value measured by a current sensor when the electronic device of the vehicle according to an embodiment of the disclosure operates.

Referring to FIGS. 5A and 5B, the power controller 15 may transmit a control signal to each of the plurality of electronic devices 12 and then check the current value measured by the current sensor 13. When the power controller 15 transmits a control signal for operating the troubled electronic device, it can be seen that the amount of change in the current value flowing through the electronic device 12 is relatively small as shown in FIG. 5A. That is, when the difference between the maximum value and the minimum value of the current value flowing through the electronic device 12 which transmitted the control signal is equal to or less than a predetermined value, the power controller 15 may determine that the electronic device 12 is in a trouble.

In addition, the power controller 15 may determine that the corresponding electronic device 12 is in a trouble when the amount of change in the current value flowing through the electronic device 12 that transmits the control signal is equal to or less than the predetermined change amount.

When the power controller 15 transmits a control signal for operating the electronic device 12 that operates normally, as shown in FIG. 5B, it can be seen that the amount of change in the current value flowing through the electronic device 12 is relatively large. That is, the power controller 15 may determine that the electronic device 12 operates normally when the difference between the maximum value and the minimum value of the current value flowing through the electronic device 12 that transmits the control signal is greater than a predetermined value.

When trouble states of the plurality of electronic devices 12 are determined, the power controller 15 may transmit a trouble state of each of the plurality of electronic devices 12 to the transceiver 18, and the transceiver 18 may transmit trouble state information of the plurality of electronic devices 12 received from the power controller 15 to the car sharing server 20 (2300).

For example, after the power controller 15 transmits a control signal to the head lamp, the current value measured by the current sensor 13 is as shown in FIG. 5A, and when the current value measured by the current sensor 13 after the power controller 15 transmits a control signal to the stop lamp is shown in FIG. 5b, the power controller 15 may transmit an information indicating that the headlamp is in a trouble to the transceiver 18, and the transceiver 18 may transmit the information indicating that the headlamp is in a trouble to the car sharing server 20.

As such, when the power controller 15 transmits a control signal for driving each of the plurality of electronic devices 12 to determine a trouble state of each of the plurality of electronic devices 12, and transmits the trouble state information of the plurality of electronic devices 12 to the car sharing server 20, the manager of the car sharing company may check the trouble state of the electronic device 12 of the vehicle 10.

In addition, the manager of the car sharing company may automatically determine the trouble state of the plurality of electronic devices 12 operated by the control of the power controller 15 instead of the plurality of controllers 14 generating trouble code information.

Although not shown in the drawings, the car sharing server 20 may match trouble state information of the plurality of electronic devices 12 received from the vehicle 10 with unique numbers of the vehicle 10 and store the same. The car sharing server 20 may easily manage the plurality of shared vehicles 10 by matching trouble state information received from the vehicle 10 with a unique number of the vehicle 10 and by storing the same.

In addition, the car sharing server 20 determines whether the vehicle 10 needs to be repaired based on the trouble states of the plurality of electronic devices 12 received from the vehicle 10, and when determining that the vehicle 10 needs to be repaired, the car sharing server 20 may transmit a repair request signal to the vehicle 10. The manager determines that the vehicle 10 needs to be repaired, and may transmit a repair request signal to the vehicle 10 through the car sharing server 20.

In the case of the autonomous vehicle, when the transceiver 18 of the vehicle 10 receives a repair request signal from the car sharing server 20, the autonomous vehicle may move to a predetermined place based on the autonomous driving system.

According to the control method of the vehicle 10 described above, the vehicle 10 can identify the trouble state of the components of the vehicle 10 or the electronic device 12 through a simple control logic without a separate manager. Through this, the driver and/or manager can take appropriate measures according to the trouble state of the vehicle (10) without having to go directly to the vehicle (10) and check them individually, the problem caused by the trouble of the vehicle (10) may be prevented.

According to an aspect of the disclosure, since the manager of the car sharing company does not need to go directly to the shared vehicle to determine whether the electronic device is in a trouble, it is possible to reduce the labor cost according to vehicle management.

In addition, the electronic device of the autonomous vehicle or the shared vehicle can be efficiently diagnosed.

Meanwhile, the disclosed embodiments may be embodied in the form of a recording medium storing instructions executable by a processor or other computer. The instructions may be stored in the form of program code and, when executed by a processor, may generate a program module to perform the operations of the disclosed embodiments. The recording medium may be embodied as non-transitory computer-readable recording medium.

The computer-readable recording medium includes all kinds of recording media in which instructions which can be decoded by a computer are stored, for example, a Read Only Memory (ROM), a Random Access Memory (RAM), a magnetic tape, a magnetic disk, a flash memory, an optical data storage device, and the like.

Although exemplary embodiments of the disclosure have been described for illustrative purposes, those skilled in the art will appreciate that various modifications, additions and substitutions are possible, without departing from the scope and spirit of the disclosure. Therefore, exemplary embodiments of the disclosure have not been described for limiting purposes.

What is claimed is:

1. A vehicle comprising:
a plurality of controllers provided in the vehicle and configured to generate trouble code information;
a plurality of electronic devices provided in the vehicle;
a power controller configured to control the plurality of electronic devices;
a transceiver configured to transmit data to a car sharing server;
a processor; and
a non-transitory storage medium containing program instructions that, when executed by the processor, causes the transceiver to:
transmit a trouble code information received from the plurality of controllers to the car sharing server when receiving a return signal of the vehicle from the car sharing server, and
transmit a trouble state information of the plurality of electronic devices received from the power controller to the car sharing server when receiving a diagnosis request signal of the vehicle from the car sharing server.

2. The vehicle according to claim 1, further comprising:
a current sensor configured to measure a current value flowing through the plurality of electronic devices,
wherein the non-transitory storage medium further containing program instructions, when executed by the processor, causes the power controller to:
transmit a control signal for operating the plurality of electronic devices when receiving the diagnosis request signal from the car sharing server, and
determine a trouble state of the plurality of electronic devices based on a difference between a maximum value and a minimum value of the current value measured by the current sensor.

3. The vehicle according to claim 2, wherein the non-transitory storage medium further containing program instructions, when executed by the processor, causes the power controller to:
determine that at least one of the plurality of electronic devices is in a trouble when a difference between the maximum value and the minimum value of the current value measured by the current sensor is less than or equal to a predetermined value after transmitting the control signal.

4. The vehicle according to claim 3, wherein the non-transitory storage medium further containing program instructions, when executed by the processor, causes the power controller to:
sequentially transmit control signals for operating each of the plurality of electronic devices, and transmit a trouble state of a given electronic device determined to be in a trouble among the plurality of electronic devices to the transceiver.

5. The vehicle according to claim 1, wherein the non-transitory storage medium further containing program instructions, when executed by the processor, causes the transceiver to:
request the plurality of controllers for the trouble code information when receiving a return signal of the vehicle from the car sharing server.

6. The vehicle according to claim 1, wherein the non-transitory storage medium further containing program instructions, when executed by the processor, causes the transceiver to:
request the power controller for trouble state information of the plurality of electronic devices when receiving a diagnosis request signal of the vehicle from the car sharing server.

7. The vehicle according to claim 1, further comprising:
a Tire Pressure Monitoring System (TPMS) configured to measure a tire air pressure of the vehicle,
wherein the non-transitory storage medium further containing program instructions, when executed by the processor causes the transceiver to:
request the tire pressure information of the vehicle to the TPMS when receiving a diagnosis request signal of the vehicle from the car sharing server and transmit the measured tire air pressure of the vehicle received from the TPMS to the car sharing server.

8. A control method of a vehicle, comprising:
receiving at least one of a return signal of the vehicle or a diagnosis request signal of the vehicle from a car sharing server;
when receiving the return signal of the vehicle from the car sharing server, transmitting trouble code information generated by a plurality of controllers provided in the vehicle to the car sharing server;
when receiving the diagnosis request signal of the vehicle from the car sharing server, determining a trouble state of a plurality of electronic devices of the vehicle; and
transmitting the trouble state of the plurality of electronic devices to the car sharing server.

9. The control method of claim 8, wherein the determining the trouble state of the plurality of electronic devices comprises:
transmitting a control signal for operating the plurality of electronic devices;
measuring a current value flowing through the plurality of electronic devices; and
determining the trouble state of the plurality of electronic devices based on a difference between a maximum value and a minimum value of current value flowing through the plurality of electronic devices.

10. The control method of claim 9, wherein the determining the trouble state of the plurality of electronic devices comprises:
determining that at least one of the plurality of electronic devices is in a trouble when a difference between a minimum value and a maximum value of current value flowing through the plurality of electronic devices is equal to or less than a predetermined value after transmitting the control signal.

11. The control method of claim 10, wherein the determining the trouble state of the plurality of electronic devices and transmitting the trouble state of the plurality of electronic devices to the car sharing server comprises:
sequentially transmitting control signals for operating each of the plurality of electronic devices; and
transmitting the trouble state of a given electronic device determined to be in a trouble among the plurality of electronic devices to the car sharing server.

12. The control method of claim 8, further comprising:
requesting the plurality of controllers for the trouble code information when receiving a return signal of the vehicle from the car sharing server.

13. The control method of claim 8, further comprising:
requesting the plurality of controllers for trouble state information of the plurality of electronic devices when receiving a diagnosis request signal of the vehicle from the car sharing server.

14. The control method of claim 8, further comprising:
when receiving a diagnosis request signal of the vehicle from the car sharing server, transmitting the tire air pressure information of the vehicle to the car sharing server.

15. A vehicle trouble diagnosis system, comprising:
a car sharing server configured to receive a return signal of the vehicle or a diagnosis request signal of the vehicle from a user terminal and to transmit at least one of the return signal or the diagnosis request signal to the vehicle; and
a vehicle configured to transmit a trouble code information of the vehicle to the car sharing server when receiving the return signal from the car sharing server and transmit a trouble state information of a plurality of electronic devices of the vehicle to the car sharing server when receiving the diagnosis request signal from the car sharing server.

16. The vehicle trouble diagnosis system of claim 15, wherein the car sharing server is configured to match at least one of the trouble code information received from the vehicle or the trouble state information of the plurality of electronic devices with a unique number of the vehicle and to store the same.

17. The vehicle trouble diagnosis system of claim 16, wherein the car sharing server is configured to determine whether to repair the vehicle based on at least one of the trouble code information received from the vehicle or the trouble state information of the plurality of electronic devices.

18. The vehicle trouble diagnosis system of claim 17, wherein the car sharing server is configured to transmit a repair request signal to the vehicle when determining that the repair of the vehicle is necessary.

19. The vehicle trouble diagnosis system of claim 18, wherein the vehicle is configured to move to a predetermined place based on an autonomous driving system when receiving the repair request signal from the car sharing server.

20. The vehicle trouble diagnosis system of claim 15, wherein the vehicle is configured to transmit a control signal for operating the plurality of electronic devices when receiving a diagnosis request signal from the car sharing server and determine a trouble state of the plurality of electronic devices based on a difference between a maximum value and a minimum value of current values flowing through the plurality of electronic devices after transmitting the control signal.
